(19) United States
(12) Patent Application Publication
(10) Pub. No.: US 2011/0303912 A1
(43) Pub. Date: Dec. 15, 2011

(54) Methods Of Manufacturing P-Type Zn Oxide Nanowires And Electronic Devices Including P-Type Zn Oxide Nanowires

(75) Inventors: Seung-nam Cha, Seoul (KR); Young-jun Park, Suwon-si (KR); Jin-pyo Hong, Seoul (KR)

(73) Assignee: SAMSUNG ELECTRONICS CO., LTD., Suwon-si (KR)

(21) Appl. No.: 13/107,151

(22) Filed: May 13, 2011

(30) Foreign Application Priority Data
Jun. 10, 2010 (KR) 10-2010-0055108

(51) Int. Cl. H01L 29/22; H01L 21/208; B82Y 99/00; B82Y 40/00

(52) U.S. Cl. 257/43; 438/502; 977/762; 977/890; 257/E29.094; 257/E21.114

(57) ABSTRACT

Example embodiments relate to methods of manufacturing p-type Zn oxide nanowires and electronic devices including the p-type Zn oxide nanowires. The method may include forming Zn oxide nanowires in an aqueous solution by using a hydrothermal synthesis method and annealing the Zn oxide nanowires to form p-type Zn oxide nanowires.

### CROSS-REFERENCE TO RELATED APPLICATION

This application claims priority under 35 U.S.C. §119 to Korean Patent Application No. 10-2010-0055108, filed on Jun. 10, 2010 in the Korean Intellectual Property Office, the disclosure of which is incorporated herein in its entirety by reference.

### BACKGROUND

1. Field

The present disclosure relates to methods of manufacturing p-type Zn oxide nanowires and electronic devices including the p-type Zn oxide nanowires. For example, example embodiments herein relate to methods of manufacturing p-type Zn oxide nanowires in which a solution including a Zn salt, a reductant, and a doping material is used to form p-type zinc oxide nanowires using a relatively low-temperature growth method.

2. Description of the Related Art

Nanowires have been noticed in various fields and are used not only in the field of optical applications (e.g., electronic devices, light emitting diodes (LED), or solar cells) but also in the fields of complementary metal oxide semiconductors (CMOS). In particular, in manufacturing higher efficiency nano light emitting and receiving devices, nanowires have been recognized as a material for increasing efficiency due to its electrical stability and relatively high conductivity.

In general, semiconductor materials may be implemented largely as n-type and p-type, and the application range of a predetermined material is determined according to the implementation of these two characteristics in the material. Si or GaN, which are representative examples of semiconductor materials, and with which n-type and p-type are implemented with relative ease, are used in various fields.

Zn oxide is a II-VI group oxide semiconductor material and has a wide direct band gap of 3.37 eV and an excitation binding energy of 60 mV. Zn oxide is synthesized with relative ease and has beneficial electrical/optical characteristics and thus is used in various semiconductor devices and optical devices.

Zn oxide usually shows n-type characteristics. Thus, a p-type Zn oxide may be relatively difficult to obtain/implement. That being said, the growth of p-type Zn oxide nanowires also poses an obstacle in terms of application of various devices.

### SUMMARY

Example embodiments relate to methods of manufacturing p-type Zn oxide nanowires by using an aqueous solution.

Example embodiments also relate to electronic devices including p-type Zn oxide nanowires.

Additional aspects of example embodiments are also set forth in the detailed description which follows while other aspects will become apparent from review or practice of the present invention.

According to a non-limiting aspect of the present invention, a method of manufacturing p-type Zn oxide nanowires may include forming a seed layer on a substrate; exposing the seed layer to an aqueous solution including a Zn salt, a reductant, and a doping material to form Zn oxide nanowires on the substrate; and annealing the Zn oxide nanowires to form the p-type Zn oxide nanowires.

The substrate may be formed of a semiconductor, a nonconductor, or a metal.

The substrate may be formed of Si, glass, plastic, or polymer.

The seed layer may be a Zn oxide layer.

The reductant may be a hexamethylenetetramine (HMTA).

The doping material may be a lithium salt.

A temperature of the aqueous solution may be from about 85° C. to about 100° C. C.

The aqueous solution may have a pH from about 10 to about 11.

The annealing may be performed at a temperature in a range from about 400° C. to about 600° C.

According to another non-limiting aspect of the present invention, an electronic device may include p-type Zn oxide nanowires. The electronic device may include a bottom electrode formed on a substrate; an n-type Zn oxide layer formed on the bottom electrode; a plurality of the p-type Zn oxide nanowires formed on the n-type Zn oxide layer, the plurality of p-type Zn oxide nanowires including lithium; and a top electrode formed on the plurality of p-type Zn oxide nanowires.

According to another non-limiting aspect of the present invention, an electronic device may include p-type Zn oxide nanowires. The electronic device may include a bottom electrode formed on a first surface of a substrate; an n-type semiconductor layer formed on an opposing second surface of the substrate; a plurality of the p-type Zn oxide nanowires formed on the n-type semiconductor layer, the plurality of p-type Zn oxide nanowires including lithium; and a top electrode formed on the plurality of p-type Zn oxide nanowires.

The substrate may be formed of an n-type semiconductor material.

### BRIEF DESCRIPTION OF THE DRAWINGS

The above and/or other aspects of example embodiments will become more apparent and readily appreciated from the following description of various non-limiting embodiments, taken in conjunction with the accompanying drawings of which:

FIGS. 1A through 1C illustrate a method of manufacturing p-type Zn oxide nanowires, according to a non-limiting embodiment of the present invention;

FIGS. 2 and 3 illustrate an electronic device including p-type Zn oxide nanowires, according to a non-limiting embodiment of the present invention;

FIG. 4 is a graph showing photoluminescence (PL) characteristics of p-type oxide nanowires, according to a non-limiting embodiment of the present invention; and

FIG. 5 is a graph showing voltage(V)-current(mA) characteristics of a diode structure including p-type Zn oxide nanowires, according to a non-limiting embodiment of the present invention.

### DETAILED DESCRIPTION

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on,” “directly connected to,” or “directly coupled to” another element or layer, there are no intervening elements or layers present. Like numbers refer to like elements throughout the specification. As used herein, the term “and/or” includes any and all combinations of one or more of the associated listed items.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, e.g., “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” may encompass both an orientation of above and below. The device may be otherwise oriented (rotated 90 degrees or at other orientations) and the spatially relative descriptors used herein interpreted accordingly.

The terminology used herein is for the purpose of describing various embodiments only and is not intended to be limiting of example embodiments. As used herein, the singular forms “a,” “an,” and “the” are intended to include the plural forms as well, unless the context clearly indicates otherwise. It will be further understood that the terms, “comprises,” “comprising,” “includes,” and/or “including,” if used herein, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing.

Unless otherwise defined, all terms (including technical and scientific terms) used herein have the same meaning as commonly understood by one of ordinary skill in the art. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Reference will now be made in further detail to non-limiting embodiments herein, examples of which are illustrated in the accompanying drawings, wherein like reference numerals refer to like elements throughout. In this regard, example embodiments herein may have different forms and should not be construed as being limited to the descriptions set forth herein. Accordingly, it should be understood that example embodiments are merely described below, by referring to the figures, to explain various aspects of the present description.

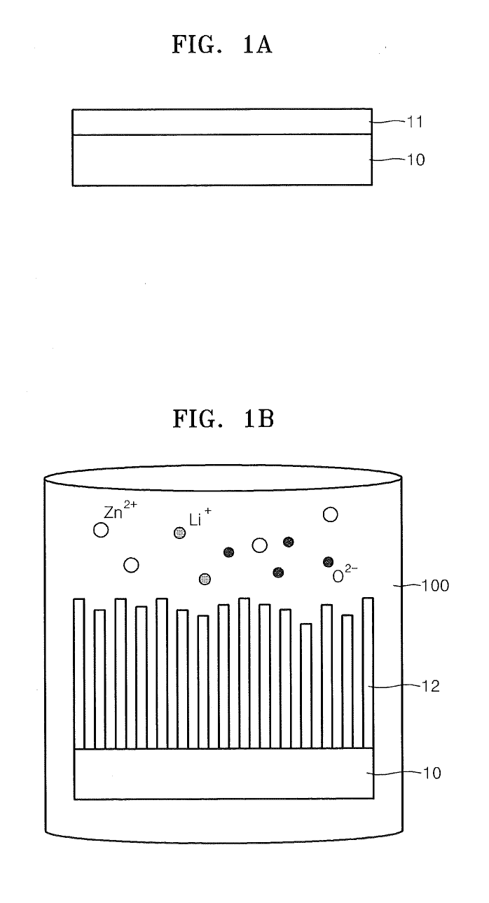

FIGS. 1A through 1C illustrate a method of manufacturing p-type Zn oxide nanowires, according to a non-limiting embodiment of the present invention.

Referring to FIG. 1A, a seed layer 11 is formed on a substrate 10 to grow ZnO oxide nanowires. The substrate 10 may be any material that is suitable for use in a semiconductor process and that is thermally and chemically stable. For example, the substrate 10 may be formed of a semiconductor, a metal, or a non-conductive substrate. In further detail, the substrate 10 may be formed of Si, glass, plastic, or polymer.

The seed layer 11 is formed to grow Zn oxide nanowires and may be a Zn oxide having a thickness from about 30 nm to about several micrometers. The seed layer 11 may be formed using an oxidization operation after forming Zn. The seed layer 11 may be formed using a vapor deposition method in a chamber.

Referring to FIG. 1B, the substrate 10 on which the seed layer 11 is formed is put into a reaction vessel 100 including an aqueous solution to grow Zn oxide nanowires 12 on the substrate 10. The aqueous solution may include a Zn salt, a reductant, and a doping material. The doping material may include a Group 1 element. In a non-limiting embodiment, the doping material may be a lithium salt. Lithium has a similar radius to an oxygen atom and thus may be doped with relative ease. For example, if lithium is substituted with the Zn of a Zn oxide, then the Zn oxide may have p-type characteristics. Hexamethylenetetramine (HMTA) may be used as the reductant, and the amount thereof may be adjusted according to an amount of the lithium salt (doping material) and according to an amount of Zn to be reduced. When heat is applied to facilitate growth of the Zn oxide nanowires 12 in the aqueous solution, Zn oxide nanowires 12 may be self-assembled by nucleation. A temperature of the aqueous solution may be maintained from about 85° C. to about 100° C.

As the Zn oxide nanowires 12 are grown on the substrate 10 in the reaction vessel 100, the Zn oxide nanowires 12 will include the atoms of the doping material (e.g., lithium atoms), and as the reaction is conducted, a pH of the entire aqueous solution may vary and affect growth of the Zn oxide nanowires 12. Accordingly, an aqueous solution including a Zn salt and a lithium salt may be continuously supplied to the reaction vessel 100. The pH of the aqueous solution in the reaction vessel 100 may be maintained in a range from about 10 to about 11, and an aqueous solution exchange system using a pH sensor may be used.

As a result of a reaction in the reaction vessel 100, the Zn oxide nanowires 12 may be grown on the substrate 10, and lithium may be included in the Zn oxide nanowires 12. Referring to FIG. 1C, by annealing the Zn oxide nanowires 12 (that are grown as described above) at a temperature from about 400° C. to about 600° C., a lithium atom is substituted with a Zn atom in the Zn oxide and oxygen vacancy is reduced. Thus, the Zn oxide nanowires 12 are transformed into p-type Zn oxide nanowires 13 by the annealing. The annealing may be performed in an oxygen atmosphere.

Consequently, according to a non-limiting embodiment of the present invention, a hydrothermal synthesis method for forming the p-type Zn oxide nanowires 13 (in which Zn oxide nanowires 12 including lithium are formed on a substrate 10 in an aqueous solution and subsequently annealed) may be provided.

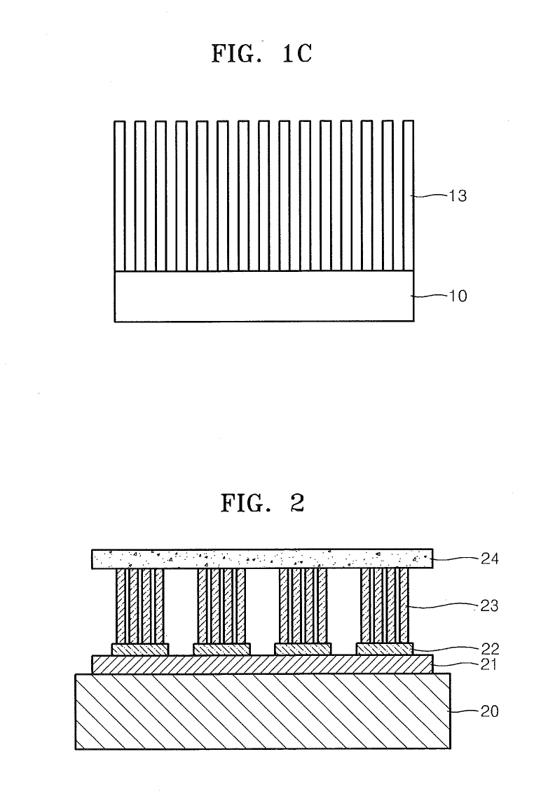

FIGS. 2 and 3 illustrate an electronic device including p-type Zn oxide nanowires, according to a non-limiting embodiment of the present invention.

Referring to FIG. 2, a bottom electrode 21 is formed on a substrate 20, an n-type Zn oxide layer 22 is formed on the bottom electrode 21, and a plurality of p-type Zn oxide nanowires 23 are formed on the n-type Zn oxide layer 22. Also, a top electrode 24 is formed on the p-type Zn oxide nanowires 23.

The n-type Zn oxide layer 22 and the p-type Zn oxide nanowires 23 may form a p-n junction. In general, a Zn oxide has n-type characteristics. As a result, the n-type Zn oxide layer 22 may be formed with relative ease on the substrate 20 by using a Zn oxide formation process. The n-type Zn oxide layer 22 may function as a seed layer for growing the p-type Zn oxide nanowires 23. Subsequently, the n-type Zn oxide layer 22 may function as an n-type semiconductor of a p-n junction device. The electronic device illustrated in FIG. 2 may be an optical device. In such a device, the n-type Zn oxide layer 22 may have a homogeneous junction structure as the p-type Zn oxide nanowires 23.

FIG. 3 illustrates an electronic device in which an n-type substrate is used (unlike the electronic device illustrated in FIG. 2). Referring to FIG. 3, a substrate 30 may be formed of an n-type semiconductor material. In a non-limiting embodiment, the substrate 30 may be formed of, for example, an n-type silicon or n-type GaN substrate. A bottom electrode 34 is formed on a first surface (for example, a lower surface) of the substrate 30, an n-type semiconductor layer 31 is formed on a second surface (for example, an upper surface) of the substrate 30, a plurality of p-type Zn oxide nanowires 32 are formed on the n-type semiconductor layer 31, and a top electrode 33 is formed on the p-type Zn oxide nanowires 32. The n-type semiconductor layer 31 may be formed using an In—Zn oxide, a Ga—In—Zn oxide, an In oxide, or GaN. Thus, the n-type semiconductor layer 31 may have a heterogeneous junction structure from the p-type Zn oxide nanowires 32. The electronic devices illustrated in FIGS. 2 and 3 may be used as optical devices.

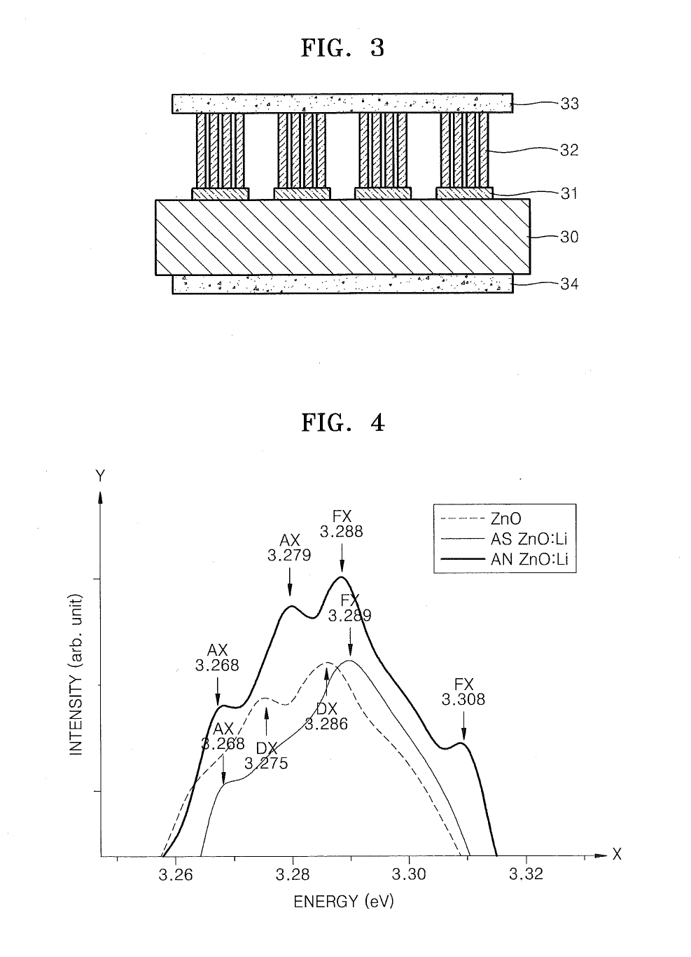

FIG. 4 is a graph showing photoluminescence (PL) characteristics of p-type oxide nanowires, according to a non-limiting embodiment of the present invention. In FIG. 4, a horizontal axis (X) denotes energy (eV), and a vertical axis Y denotes intensity. AX denotes an acceptor level bound exciton, DX denotes a donor bound exciton, and FX denotes free excitons. If a sample to be measured is a p-type material, then an AX peak may be observed from the curve of the PL characteristics of the sample.

Referring to FIG. 4, the curve of the PL characteristics of Zn oxide (ZnO) hardly shows an AX peak. However, referring to the curve of the PL characteristics of Zn oxide (AS ZnO:Li), which is doped with lithium and not annealed, an AX peak having a relatively low density is seen. Also, referring to the curve of the PL characteristics of Zn oxide (AN ZnO:Li), which is doped with lithium and annealed, an AX peak having a relatively high density is observed. Thus, as described above, p-type Zn oxide nanowires may be formed by annealing nanowires formed of Zn oxide and a suitable doping material (e.g., lithium).

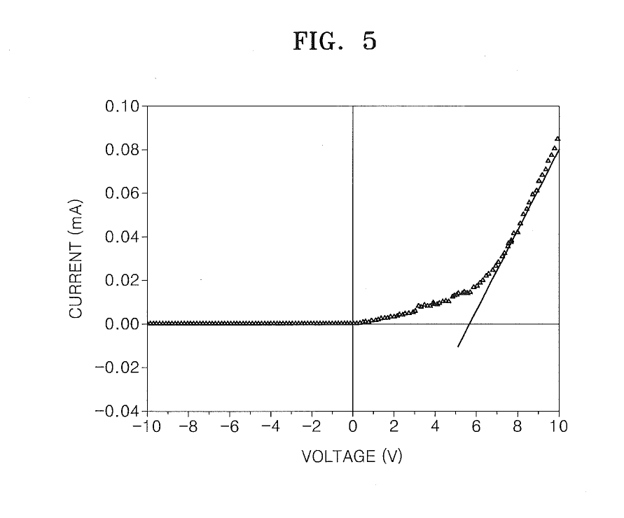

FIG. 5 is a graph showing voltage(V)-current(mA) characteristics of a diode structure in which p-type Zn oxide nanowires are used, according to a non-limiting embodiment of the present invention. The graph is the result of a diode structure that includes an n-type Zn oxide layer having a thickness of about 10 nm, on which p-type Zn oxide nanowires doped with about 5 micrometer-thick lithium is formed. A voltage is applied through electrodes to two sides of the diode structure to measure a current.

Referring to FIG. 5, a typical curve of a p-n diode may be obtained. Consequently, by forming Zn oxide nanowires including a suitable doping material (e.g., lithium) and annealing the same, p-type Zn oxide nanowires may be formed.

As described above, according to example embodiments of the present invention, a Zn oxide nanowire may be formed in an aqueous solution and annealed to thereby form p-type Zn oxide nanowires with relative ease.

While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims. Thus, the descriptions of features or aspects within one embodiment should be considered as available for other similar features or aspects in other embodiments.

What is claimed is:

1. A method of manufacturing p-type Zn oxide nanowires, the method comprising:
forming a seed layer on a substrate;
exposing the seed layer to an aqueous solution including a Zn salt, a reductant, and a doping material to form Zn oxide nanowires on the substrate; and
annealing the Zn oxide nanowires to form the p-type Zn oxide nanowires.

2. The method of claim 1, wherein the substrate is formed of a semiconductor, a nonconductor, or a metal.

3. The method of claim 1, wherein the substrate is formed of Si, glass, plastic, or polymer.

4. The method of claim 1, wherein the seed layer is formed of Zn oxide.

5. The method of claim 1, wherein the reductant is a hexamethylenetetramine (HMTA).

6. The method of claim 1, wherein the doping material is a lithium salt.

7. The method of claim 1, wherein the aqueous solution is maintained at a temperature ranging from about 85° C. to about 100° C.

8. The method of claim 1, wherein the aqueous solution has a pH ranging from about 10 to about 11.

9. The method of claim 1, wherein the annealing is performed at a temperature ranging from about 400° C. to about 600° C.

10. An electronic device comprising:
a bottom electrode on a substrate;
an n-type Zn oxide layer on the bottom electrode;
a plurality of p-type Zn oxide nanowires on the n-type Zn oxide layer, the plurality of p-type Zn oxide nanowires including lithium; and
a top electrode on the plurality of p-type Zn oxide nanowires.

11. An electronic device comprising:
a bottom electrode on a first surface of a substrate;
an n-type semiconductor layer on an opposing second surface of the substrate;
a plurality of p-type Zn oxide nanowires on the n-type semiconductor layer, the plurality of p-type Zn oxide nanowires including lithium; and
a top electrode on the plurality of p-type Zn oxide nanowires.

12. The electronic device of claim 11, wherein the substrate includes an n-type semiconductor material.
